(19) United States
(12) Patent Application Publication
(10) Pub. No.: US 2017/0016109 A1
(43) Pub. Date: Jan. 19, 2017

(54) THIN FILM DEPOSITING APPARATUS AND THE THIN FILM DEPOSITING METHOD USING THE SAME

(71) Applicant: SAMSUNG DISPLAY CO., LTD., Yongin-si (KR)

(72) Inventors: Yong-Suk Lee, Yongin-si (KR); Myung-Soo Huh, Yongin-si (KR); Cheol-Rae Jo, Yongin-si (KR); Sang-Hyuk Hong, Yongin-si (KR); Jeong-Ho Yi, Yongin-si (KR); Suk-Won Jung, Yongin-si (KR); Sun-Ho Kim, Yongin-si (KR); Mi-Ra An, Yongin-si (KR)

(21) Appl. No.: 15/277,977

(22) Filed: Sep. 27, 2016

Related U.S. Application Data
(62) Division of application No. 13/535,268, filed on Jun. 27, 2012.

(30) Foreign Application Priority Data
Dec. 28, 2011 (KR) 10-2011-0144983

(51) Int. Cl. C23C 14/12; C23C 14/58; C23C 14/24; C23C 14/22

(52) U.S. Cl. CPC C23C 14/12; C23C 14/228; C23C 14/584; C23C 14/246

(57) ABSTRACT

A thin film depositing apparatus and a thin film deposition method using the apparatus. The thin film depositing apparatus includes a chamber configured to have a substrate mounted therein, an ejection unit configured to move in the chamber and to eject a deposition vapor to the substrate, and a source supply unit configured to supply a source of the deposition vapor to the ejection unit.

### CROSS-REFERENCE TO RELATED PATENT APPLICATION

This application is a divisional of U.S. patent application Ser. No. 13/535,268, filed on Jun. 27, 2012, which claims priority to, and the benefit of, Korean Patent Application No. 10-2011-0144983, filed on Dec. 28, 2011, the entire content of both of which being incorporated herein by reference.

### BACKGROUND

1. Field

Embodiments of the present invention relate to a thin film depositing apparatus for generating vapor of a deposition source and depositing the vapor on a surface of an object.

2. Description of the Related Art

In a thin film manufacturing process, such as the forming of a thin film of an organic light emitting display apparatus, a deposition operation in which vapor of a deposition source is generated and attached on a surface of an object, such as a substrate, is frequently used.

Recently, as the size of organic light emitting display apparatuses has increased, a corresponding surface area of a substrate on which deposition is to be performed has also increased. Thus, it is difficult to form a uniform film on the entire surface area of the substrate while both the substrate and a deposition source are fixed.

To address the above problem, according to the related art, a deposition source is fixed and a substrate is moved with respect thereto to form a uniform film on the entire surface area of the substrate. However, in this case, sufficient space for the large-sized substrate must be provided, and thus, the size of a depositing apparatus is increased considerably.

### SUMMARY

Embodiments of the present invention provide a thin film depositing apparatus to perform deposition while moving a deposition source with respect to an object, and a thin film deposition method using the thin film depositing apparatus.

According to an aspect of embodiments of the present invention, there is provided a thin film depositing apparatus including a chamber configured to have a substrate mounted therein, an ejection unit configured to move in the chamber and to eject a deposition vapor to the substrate, and a source supply unit configured to supply a source of the deposition vapor to the ejection unit.

The source of the deposition vapor may include a liquid monomer, and an inert gas mixed with the monomer as a carrier gas of the monomer, and the source supply unit may include a carrier gas supply unit configured to store and supply the inert gas, and a monomer supply unit configured to store and supply the liquid monomer.

The monomer supply unit may include a syringe pump configured to supply the monomer to the ejection unit.

The thin film depositing apparatus may further include a plurality of syringe pumps configured to alternately supply the monomer.

The thin film depositing apparatus may further include a monomer storage detachably connected to the syringe pumps and configured to store the monomer.

The ejection unit may include an ejection portion facing the substrate, wherein a heater is configured to vaporize the source at the ejection portion, a first supply line for connecting the monomer supply unit and the ejection portion, a second supply line for connecting the carrier gas supply unit and the ejection portion, a first flow rate controller at the first supply line for controlling an amount of the monomer supplied to the ejection portion, and a second flow rate controller at the second supply line for controlling an amount of the carrier gas supplied to the ejection portion.

The thin film depositing apparatus may further include a pressure sensor configured to measure a pressure corresponding to the monomer and located at the first supply line.

The thin film depositing apparatus may further include a third supply line for connecting the first supply line and the second supply line, wherein the third supply line is configured to allow the carrier gas to enter the first supply line when the pressure sensor measures pressure below a normal range.

The thin film depositing apparatus may further include an ultraviolet ray lamp at the ejection unit that is configured to irradiate ultraviolet rays to the substrate.

The chamber may be configured to have the substrate vertically mounted therein, and the ejection unit may be configured to move in a vertical direction while facing the substrate.

According to another aspect of embodiments of the present invention, there is provided a thin film deposition method, the method including preparing an ejection unit for ejecting a deposition vapor in a chamber, preparing a source supply unit for supplying a source of the deposition vapor to the ejection unit in the chamber, mounting a substrate in the chamber, supplying the source to the ejection unit by operating the source supply unit, moving the ejection unit with respect to the substrate, and ejecting the deposition vapor.

The source of the deposition vapor may include a liquid monomer, and an inert gas mixed with the monomer as a carrier gas of the monomer.

The thin film deposition method may further include operating a syringe pump in the source supply unit to supply the monomer.

The thin film deposition method may further include alternately operating a plurality of syringe pumps to supply the monomer to the ejection unit.

The thin film deposition method may further include connecting a monomer storage to the plurality of syringe pumps, and storing a monomer.

The ejecting of the deposition vapor may include mixing the monomer and the carrier gas while controlling respective supply amounts of the monomer and the carrier gas in a first supply line and a second supply line through which the monomer and the carrier gas respectively pass, vaporizing a source including a mixture of the monomer and the carrier gas by heating the source, moving the ejection unit with respect to the substrate, and depositing the vaporized deposition vapor on substantially an entire surface of the substrate.

The thin film deposition method may further include measuring a pressure corresponding to the monomer supplied to the ejection unit.

The thin film deposition method may further include passing the carrier gas to the first supply line via a third supply line connecting the first and second supply lines when the measured pressure is below a normal range.

The thin film deposition method may further include irradiating ultraviolet rays toward the substrate.

The substrate may be vertically mounted in the chamber, and the ejection unit may be moved in a vertical direction while facing the substrate.

### BRIEF DESCRIPTION OF THE DRAWINGS

The above and other features and aspects of embodiments of the present invention will become more apparent by describing in detail exemplary embodiments thereof with reference to the attached drawings in which:

FIG. 1 is a schematic block diagram of a structure of a thin film depositing apparatus according to an embodiment of the present invention;

FIG. 2 is a schematic view of a structure of a monomer supply unit of a source supply unit of the thin film depositing apparatus of the embodiment shown in FIG. 1 according to an embodiment of the present invention; and

FIG. 3 is a schematic view of a structure of an ejection unit of the thin film depositing apparatus of the embodiment shown in FIG. 1 according to an embodiment of the present invention.

### DETAILED DESCRIPTION

Embodiments of the present invention will now be described more fully with reference to the accompanying drawings, in which exemplary embodiments of the invention are shown.

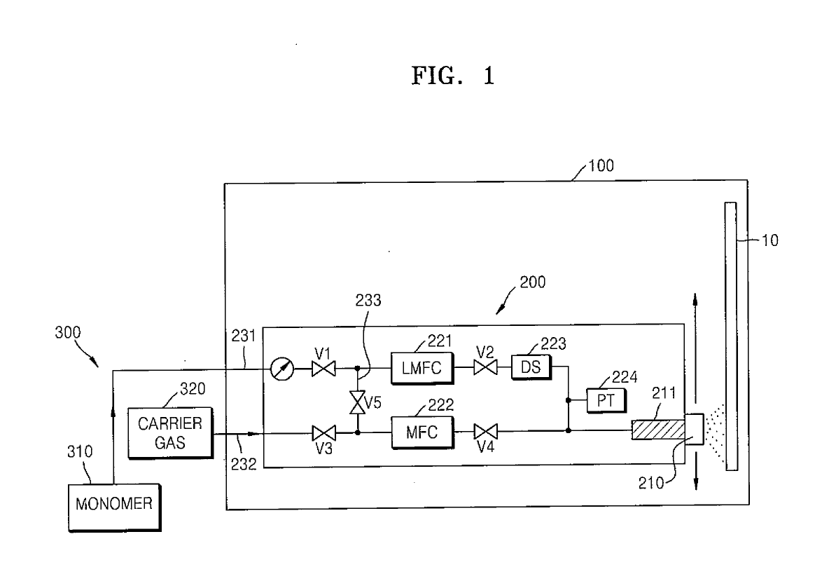

First, a thin film depositing apparatus according to an embodiment of the present invention will be described with reference to FIG. 1. FIG. 1 is a schematic block diagram of a structure of a thin film depositing apparatus according to an embodiment of the present invention. The thin film depositing apparatus of FIG. 1 includes a chamber 100 in which a substrate 10, which is a deposition target, may be fixed, an ejection unit 200 that generates a deposition vapor by moving within the chamber 100 in a vertical direction, and a source supply unit 300 that supplies a deposition source to the ejection unit 200. Thus, deposition is performed such that while the substrate 10 is mounted in the chamber 100, a deposition source is supplied from the source supply unit 300 to the ejection unit 200, and the ejection unit 200 vertically moves along the substrate 10 that is vertically mounted to eject a deposition vapor on substantially the entire surface of the substrate 10. Accordingly, deposition is performed while the substrate 10 is in a fixed state, and the ejection unit 200 moves within the surface area of the substrate 10, and thus, space occupancy rate of the chamber 100 is considerably lowered, and as the ejection unit 200 moves vertically, space occupancy rate thereof on the plane is particularly reduced.

Hereinafter, structures of the units with which low space occupancy rates as described above may be provided, and with which stable deposition may be performed, will be described in detail.

First, the source supply unit 300 includes a monomer supply unit (“MONOMER”) 310 that stores a liquid monomer and supplies the same to the ejection unit 200 via a first supply line 231 and a carrier gas supply unit (“CARRIER GAS”) 320 that stores inert gas such as argon (Ar), which is a carrier gas, and supplies the same to the ejection unit 200 via a second supply line 232. That is, according to the current embodiment of the present invention, not only monomer as a deposition source is supplied, but a carrier gas is mixed with the monomer as well to facilitate transportation thereof and to prevent/reduce the likelihood of clogging of first through third supply lines 231, 232, and 233 due to the deposition source. Avoidance of clogging using a carrier gas will be described later.

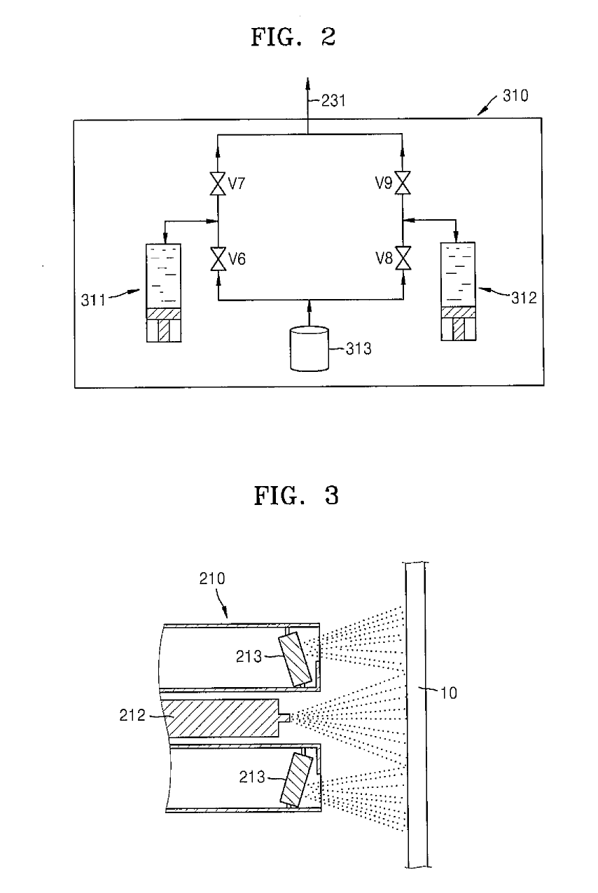

FIG. 2 is a schematic view of a structure of the monomer supply unit 310 of the source supply unit 300 of the thin film depositing apparatus of the embodiment shown in FIG. 1 according to an embodiment of the present invention. The monomer supply unit 310 may have a structure as illustrated in FIG. 2. First, a plurality of syringe pumps 311 and 312 which temporarily store monomer to be transmitted through the first supply line 231 are included. Monomer is supplied from a detachable monomer storage 313 and is charged in (e.g., stored in) each of the syringe pumps 311 and 312. In a deposition operation, the monomer is supplied to the ejection unit 200 (FIG. 1) via the first supply line 231. The plurality of syringe pumps 311 and 312 are included so that charging and supplying operations are easily and continuously performed by alternately using the plurality of syringe pumps 311 and 312. For example, when monomer is being supplied via the syringe pump 311 on the left side to the ejection unit 200 while monomer is supplied from the monomer storage 313 and charged in the syringe pump 312 on the right side during the supply of monomer via the syringe pump 311, valves V7 and V8 are opened, and valves V6 and V9 are closed. Accordingly, the monomer ejected from the syringe pump 311 on the left side passes through the opened valve V7 to be supplied to the ejection unit 200 via the first supply line 231, and the monomer of the monomer storage 313 is charged in the syringe pump 312 on the right side through the opened valve V8. When the monomer of the syringe pump 311 on the left side is consumed, the valves V7 and V8 are closed, and the valves V6 and V9 are opened. Accordingly, the monomer that is ejected from the syringe pump 312 on the right side passes through the opened valve V9 to be supplied to the ejection unit 200 via the first supply line 231, and monomer of the monomer storage 313 is charged in the syringe pump 311 on the left side through the opened valve V6. By alternately using the plurality of syringe pumps 311 and 312, monomer may be continuously charged and supplied in an easier manner. While only the single monomer storage 313 is connected according to the current embodiment of the present invention, a plurality of monomer storages 313 may be connected (e.g., alternately connected like the plurality of syringe pumps 311 and 312) in other embodiments of the present invention.

Next, as illustrated in FIG. 1, the ejection unit 200 includes an ejection portion 210 in which a heater 211 for evaporating a deposition source is mounted, a first flow rate controller (“LMFC”) 221 that is mounted at the first supply line 231 to control a supply amount of monomer to the ejection unit 200, and a second flow rate controller (“MFC”) 222 that is mounted at the second supply line 232 to control a supply amount of a carrier gas to the ejection portion 210. Accordingly, the monomer supplied through the first supply line 231 is controlled to be in an appropriate amount by the first flow rate controller 221, a carrier gas supplied through the second supply line 232 is controlled to be in an appropriate amount by the second flow rate controller 222, and the monomer and the carrier gas are mixed. While deposition is performed, valves V1, V2, V3, and V4 are opened, while a valve V5 is closed.

In addition, a sensor (“DS”) 223 for measuring monomer density in the first supply line 231 is included, and a pressure sensor (“PT”) 224 is included.

Also, a third supply line 233 that is opened or closed via the valve V5, and that connects the first and second supply lines 231 and 232, is included. The first and second supply lines 231 and 232 are connected via the third supply line 233 if the above-described clogging is to be avoided. That is, when a pressure value measured by the pressure sensor 224 is below a normal range, the first supply line 231 may be becoming clogged, indicating that monomer is not being properly supplied. To address this, the valve V5 is opened so that the carrier gas entering the second supply line 232 passes via the third supply line 233 to enter the first supply line 231. In other words, purging using an inert gas is performed.

In addition, the monomer and the carrier gas, which are controlled to be in an appropriate amount and supplied by using the first and second flow rate controllers 221 and 222, are mixed and then sent to the ejection portion 210.

The heater 211 is installed at the ejection portion 210 so as to heat the monomer mixed with the carrier gas to generate a deposition vapor. Also, as illustrated in FIG. 3, the ejection portion 210 may include an ejection nozzle 212 that ejects the deposition vapor on a surface of the substrate 10, and an ultraviolet ray lamp 213 that irradiates ultraviolet rays to the substrate 10 to facilitate hardening of the deposition layer. That is, a monomer vapor is ejected through the ejection nozzle 212 to form a deposition layer on the substrate 10, and immediately or very soon after that, an ultraviolet ray is irradiated from the ultraviolet ray lamp 213 so as to quickly perform hardening.

The ejection unit 200 including the ejection portion 210 is installed to be movable in a vertical direction along the entire surface of the substrate 10 that is set up in a vertical direction. An instrument for vertically moving the ejection unit 200 may be a typical reciprocal movement (e.g., oscillating movement) instrument such as, for example, a driving cylinder, a ball screw, or a transfer belt.

The thin film depositing apparatus having the above-described structure may be operated as described below.

First, to perform deposition, the substrate 10 is fixed vertically in the chamber 100 as illustrated in FIG. 1. Then, a vacuum state of less than 9.9×10⁻⁵ Pa is created in the chamber 100, and the heater 211 of the ejection portion 210 is operated to raise a temperature of the ejection portion 210 to a level at which a deposition vapor may be generated. The ejection portion 210 is put on standby at a position facing a lowermost end portion of the substrate 10, as illustrated in FIG. 1.

Then, when the temperature of the ejection portion 210 reaches a deposition temperature, the valves V1, V2, V3, and V4 are opened, and the first and second flow rate controllers 221 and 222 are operated. Here, the valves V3 and V4 are first opened to first supply a carrier gas from the carrier gas supply unit 320 to the ejection portion 210, thereby adjusting a set flow rate. Then, the valves V1 and V2 are opened to operate the syringe pumps 311 and 312 of the monomer supply unit 310 to supply a monomer. Since the two syringe pumps 311 and 312 are alternately used, one of them may be used in supplying while the other may be used in charging a monomer or may be on standby for supply.

Here, when a pressure measured at the pressure sensor 224 is below a set range, the valve V5 is opened to perform purging with respect to the first supply line 231.

When a normal pressure is measured, this indicates that a monomer is supplied normally, and thus, the valve V5 is closed, and the ejection portion 210 is moved in a vertical direction to perform deposition on substantially the entire surface of the substrate 10.

As described above, a monomer vapor is ejected to the substrate 10 via the ejection nozzle 212, and then an ultraviolet ray is irradiated from the ultraviolet ray lamp 213 to accelerate hardening of a deposition layer.

Then, when a monomer of one of the two syringe pumps 311 and 312 is consumed during deposition, the syringe pump in use is converted (e.g., automatically converted) to the other syringe pump to use the monomer of the same.

Deposition may be performed in the above-described manner, and when the deposition is completed, the syringe pumps 311 and 312 are stopped, the ultraviolet ray lamp 213 is turned off, and the valves V1, V2, V3, and V4 are all closed. Here, the valves V1 and V2 may preferably be closed first, and then the valves V3 and V4 may be closed after purging of an inert gas with respect to the ejection portion 210 is performed for a relatively short while.

Accordingly, by using the thin film depositing apparatus described above, deposition is performed by moving the ejection unit within a range of the substrate while having the substrate in a fixed state, and thus, the size of the thin film depositing apparatus may be reduced. In addition, as a mixture of the monomer and the carrier gas is used, a deposition source may be easily supplied.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

What is claimed is:

1. A thin film deposition method, comprising:
preparing an ejection unit for ejecting a deposition vapor in a chamber,
preparing a source supply unit for supplying a source of the deposition vapor to the ejection unit in the chamber;
mounting a substrate in the chamber;
supplying the source to the ejection unit by operating the source supply unit;
moving the ejection unit with respect to the substrate; and
ejecting the deposition vapor.

2. The thin film deposition method of claim 1, wherein the source of the deposition vapor comprises:
a liquid monomer; and
an inert gas mixed with the monomer as a carrier gas of the monomer.

3. The thin film deposition method of claim 2, further comprising operating a syringe pump in the source supply unit to supply the monomer.

4. The thin film deposition method of claim 3, further comprising alternately operating a plurality of syringe pumps to supply the monomer to the ejection unit.

5. The thin film deposition method of claim 4, further comprising: connecting a monomer storage to the plurality of syringe pumps; and
storing a monomer.

6. The thin film deposition method of claim 2, wherein the ejecting of the deposition vapor comprises:
mixing the monomer and the carrier gas while controlling respective supply amounts of the monomer and the carrier gas in a first supply line and a second supply line through which the monomer and the carrier gas respectively pass;
vaporizing a source comprising a mixture of the monomer and the carrier gas by heating the source;
moving the ejection unit with respect to the substrate; and
depositing the vaporized deposition vapor on substantially an entire surface of the substrate.

7. The thin film deposition method of claim 6, further comprising measuring a pressure corresponding to the monomer supplied to the ejection unit.

8. The thin film deposition method of claim 7, further comprising passing the carrier gas to the first supply line via a third supply line connecting the first and second supply lines when the measured pressure is below a normal range.

9. The thin film deposition method of claim 1, further comprising irradiating ultraviolet rays toward the substrate.

10. The thin film deposition method of claim 1, wherein the substrate is vertically mounted in the chamber, and
wherein the ejection unit is moved in a vertical direction while facing the substrate.
